(19) United States
(12) Patent Application Publication
(10) Pub. No.: US 2017/0243819 A1
(43) Pub. Date: Aug. 24, 2017

(54) STACKED DEVICE, MANUFACTURING METHOD, AND ELECTRONIC INSTRUMENT

(71) Applicant: Sony Semiconductor Solutions Corporation, Atsugi-shi, Kanagawa (JP)

(72) Inventors: Yoshihisa KAGAWA, Kanagawa (JP); Nobutoshi FUJII, Kanagawa (JP); Takeshi MATSUNUMA, Kanagawa (JP)

(21) Appl. No.: 15/514,870

(22) PCT Filed: Sep. 28, 2015
(86) PCT No.: PCT/JP2015/077241

§ 371 Date: Mar. 28, 2017

(30) Foreign Application Priority Data
Oct. 8, 2014 (JP) 2014-207129

(51) Int. Cl. H01L 23/522; H01L 23/498; H01L 27/146; H01L 21/48

(52) U.S. Cl. CPC H01L 23/5225; H01L 21/4853; H01L 21/4857; H01L 21/486; H01L 23/49822; H01L 23/5226; H01L 27/14636; H01L 27/14623

(57) ABSTRACT

The present disclosure relates to a stacked device, a manufacturing method, and an electronic instrument, capable of suppressing adverse effects of noise generated from one substrate, onto the other substrate. A first metal layer is formed on a bonding surface of one substrate, and a second metal layer is formed on a bonding surface of the other substrate stacked with the one substrate. Subsequently, an electromagnetic wave shield structure that interrupts an electromagnetic wave between the one substrate and the other substrate is provided by bonding the metal layer of the one substrate with the metal layer of the other substrate and by performing potential fixing. The present technology can be applied, for example, to a stacked CMOS image sensor.

### TECHNICAL FIELD

The present disclosure relates to a stacked device, a manufacturing method, and an electronic instrument, particularly relates to the stacked device, the manufacturing method, and the electronic instrument, capable of suppressing adverse effects of noise generated from one substrate, onto the other substrate.

### BACKGROUND ART

In a known electronic instrument having an imaging function, such as a digital still camera and a digital video camera, a solid-state imaging element such as a charge coupled device (CCD) and a complementary metal oxide semiconductor (CMOS) image sensor is employed, for example.

Moreover in recent years, a technology has been developed to manufacture a solid-state imaging element using a stacked device including a plurality of stacked substrates, such as a semiconductor apparatus disclosed in Patent Documents 1 and 2.

In addition, with the solid-state imaging apparatus disclosed in Patent Document 3, a technology of forming a light shield layer with a structure in which all pasting surfaces are metal when viewed from an upper or a lower direction, by arranging a plurality of metal dummy patterns in a zigzag shape on a bonding surface.

### CITATION LIST

### Patent Document

[Patent Document 1] JP 2011-96851 A
[Patent Document 2] JP 2012-256736 A
[Patent Document 3] JP 2012-164870 A

### SUMMARY OF THE INVENTION

### Problems to be Solved by the Invention

Meanwhile, with a known stacked device, there is a possibility that, for example, noise due to an electromagnetic wave generated with operation of one substrate produces adverse effects such as causing malfunction on the other substrate. In order to suppress such adverse effects, there is a demand for providing, between the substrates, a structure that interrupts the electromagnetic wave. Meanwhile, a metal structure in a stacked device disclosed in the above-described Patent Document 3, for example, is provided for the purpose of shielding light, and thus, dummy patterns arranged on a bonding surface are electrically floating, making it difficult to interrupt the above-described electromagnetic wave.

The present disclosure is made in view of this circumstance and intended to suppress adverse effects of noise generated from one substrate, onto the other substrate.

### Solutions to Problems

A stacked device according to one aspect of the present disclosure includes a first metal layer formed on one substrate of a plurality of substrates formed with at least two stacked layers, and a second metal layer formed on the other substrate stacked with the one substrate, in which an electromagnetic wave shield structure that interrupts an electromagnetic wave between the one substrate and the other substrate is provided by bonding the first metal layer and the second metal layer with each other and performing potential fixing.

A stacked device manufacturing method according to one aspect of the present disclosure includes steps of forming a first metal layer on one substrate of a plurality of substrates formed with at least two stacked layers, forming a second metal layer on the other substrate stacked with the one substrate, and providing an electromagnetic wave shield structure that interrupts an electromagnetic wave between the one substrate and the other substrate by bonding the first metal layer and the second metal layer with each other and performing potential fixing.

An electronic instrument according to one aspect of the present disclosure is equipped with a stacked device including a first metal layer formed on one substrate of a plurality of substrates formed with at least two stacked layers and including a second metal layer formed on the other substrate stacked with the one substrate, in which an electromagnetic wave shield structure that interrupts an electromagnetic wave between the one substrate and the other substrate is provided by bonding the first metal layer and the second metal layer with each other and performing potential fixing.

According to one aspect of the present disclosure, a first metal layer is formed on one substrate of a plurality of substrates formed with at least two stacked layers, and a second metal layer is formed on the other substrate stacked with the one substrate. Subsequently, an electromagnetic wave shield structure for interrupting an electromagnetic wave between the one substrate and the other substrate is provided by bonding the metal layer of the one substrate with the metal layer of the other substrate and performing potential fixing.

### Effects of the Invention

According to one aspect of the present disclosure, it is possible to suppress adverse effects of noise generated from one substrate, onto the other substrate.

### BRIEF DESCRIPTION OF DRAWINGS

FIG. 1 is a diagram illustrating an exemplary configuration of a stacked device according to a first embodiment of the present technology.

FIG. 2 is a diagram illustrating a method for manufacturing a stacked device.

FIG. 3 is a diagram illustrating a method for manufacturing a stacked device.

FIG. 4 is a diagram illustrating a method for manufacturing a stacked device.

FIG. 5 is a diagram illustrating an exemplary configuration of a stacked device according to a second embodiment.

FIG. 6 is a diagram illustrating an exemplary configuration of a stacked device according to a third embodiment.

FIG. 7 is a diagram illustrating an exemplary configuration of a stacked device according to a fourth embodiment.

FIG. 8 is a diagram illustrating an exemplary configuration of a stacked device according to a fifth embodiment.

FIG. 9 is a diagram illustrating an exemplary configuration of a stacked device according to a sixth embodiment.

FIG. 10 is a diagram illustrating an exemplary configuration of a stacked device according to a seventh embodiment.

FIG. 11 is a diagram illustrating a method for manufacturing a stacked device.

FIG. 12 is a diagram illustrating a method for manufacturing a stacked device.

FIG. 13 is a block diagram illustrating an exemplary configuration of an imaging apparatus mounted on an electronic instrument.

### MODE FOR CARRYING OUT THE INVENTION

Hereinafter, specific embodiments of the present technology will be described in detail with reference to the drawings.

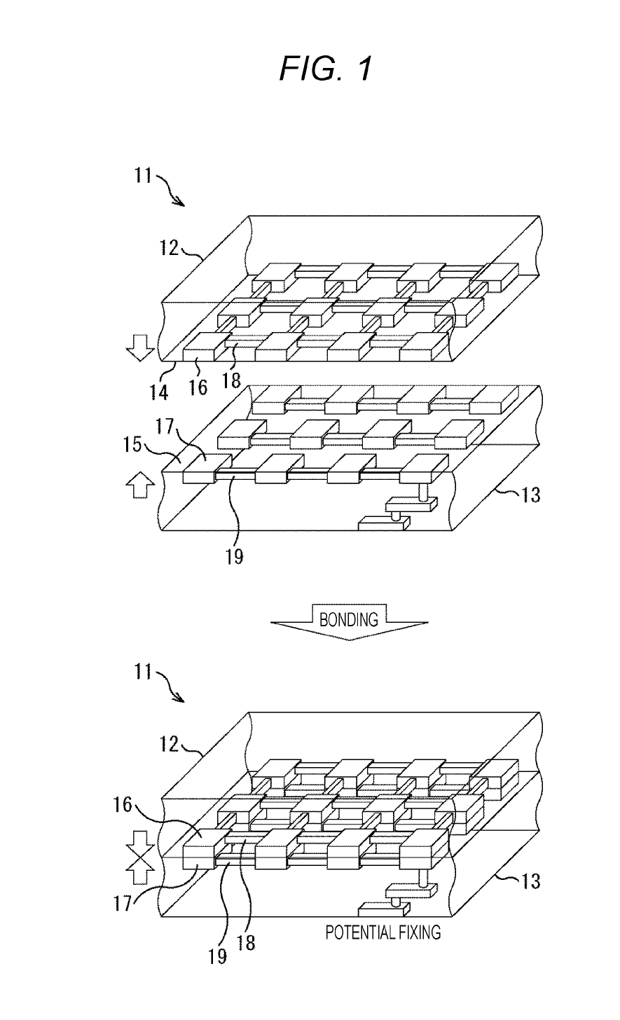

FIG. 1 is a diagram illustrating an exemplary configuration of a stacked device according to a first embodiment of the present technology.

FIG. 1 schematically illustrates a perspective view of a structure of a stacked device 11, the stacked device 11 being formed with an upper side substrate 12 and a lower side substrate 13, stacked with each other. With the stacked device 11, it is possible to constitute a solid-state imaging element such as a CMOS image sensor. In this configuration, for example, the upper side substrate 12 is assumed to be a sensor substrate on which a photodiode to constitute a pixel, a plurality of transistors, or the like, are formed, and the lower side substrate 13 is assumed to be a peripheral circuit substrate on which a drive circuit to drive pixels, a control circuit, or the like, are formed.

As illustrated in an upper side of FIG. 1, the upper side substrate 12 and the lower side substrate 13 are formed separately from each other. Subsequently, by bonding a bonding surface 14 (surface facing downward in FIG. 1) of the upper side substrate 12 with a bonding surface 15 (surface facing upward in FIG. 1) of the lower side substrate 13 by pasting the surfaces together, the integrated stacked device 11 is formed as illustrated in the lower side in FIG. 1.

In addition, there is provided a metal layer on which a plurality of bonding pads 16 is formed so as to be exposed on the bonding surface 14 of the upper side substrate 12, and together with this, there is provided a metal layer on which a plurality of bonding pads 17 is formed so as to be exposed on the bonding surface 15 of the lower side substrate 13. Each of the bonding pads 16 and the bonding pads 17 is formed of conductive metal, for example, and is connected to an element (not illustrated) provided on each of the upper side substrate 12 and the lower side substrate 13.

Moreover, the plurality of bonding pads 16 on the upper side substrate 12 and the plurality of bonding pads 17 on the lower side substrate 13 are formed at mutually corresponding positions when the upper side substrate 12 and the lower side substrate 13 are bonded with each other. Accordingly, the stacked device 11 is configured such that the upper side substrate 12 and the lower side substrate 13 are bonded with each other by metal-bonding the bonding pad 16 and the bonding pad 17 with each other on their entire surfaces.

Moreover, the plurality of bonding pads 16 on the upper side substrate 12 is arranged independently with each other at a predetermined interval between each other, while the plurality of bonding pads 17 on the lower side substrate 13 are arranged independently at a predetermined interval between each other. For example, each of the bonding pad 16 and the bonding pad 17 is formed into a rectangular shape with a side length of 0.1 μm to 100 μm, and is arranged in a pattern at an interval of 0.005 μm to 1000 μm. Note that each of the bonding pad 16 and the bonding pad 17 is not limited to the rectangular shape but may be a circular shape.

Moreover, the upper side substrate 12 is configured such that the adjoining bonding pads 16 are connected via coupling wiring 18 formed in a same layer as the layer of the bonding pad 16, and the lower side substrate 13 is configured such that the adjoining bonding pads 17 are connected via coupling wiring 19 formed in a same layer as the layer of the bonding pad 17. Furthermore, at least one of the plurality of bonding pads 16 and the plurality of bonding pads 17 is connected to a circuit electrically fixed. In a configuration example of FIG. 1, for example, one of the bonding pads 17 on the lower side substrate 13 is potential-fixed.

The stacked device 11 with this configuration is capable of interrupting an electromagnetic wave between the upper side substrate 12 and the lower side substrate 13 by its electromagnetic wave shield configuration achieved by bonding the bonding pad 16 and the bonding pad 17 and then, by performing potential fixing. Accordingly, for example, it is possible to suppress a situation where the noise due to an electromagnetic wave generated at the time of operation of the upper side substrate 12 produces adverse effects, such as malfunction, onto the lower side substrate 13. Moreover, similarly, it is possible to suppress a situation where the noise due to an electromagnetic wave generated at the time of operation of the lower side substrate 13 produces adverse effects, such as malfunction, onto the upper side substrate 12.

Moreover, by providing the electromagnetic wave shield configuration on the bonding surface of each of the upper side substrate 12 and the lower side substrate 13, it is possible to achieve a configuration that enables electrical connection between the upper side substrate 12 and the lower side substrate 13 and interruption of the electromagnetic wave to be performed in a same layer. With this configuration, it is possible to reduce manufacturing costs compared with a configuration in which a function of performing electrical connection and a function of interrupting electromagnetic waves are provided in different layers.

Note that the stacked device 11 can be configured to include the electromagnetic wave shield configuration formed with the bonding pad 16 and the bonding pad 17, on the entire surface of the stacked device 11, for example. Alternatively, for example, it is allowable to arrange the electromagnetic wave shield configuration formed with the bonding pad 16 and the bonding pad 17, in a region in the vicinity of a specific circuit that generates an electromagnetic wave that produces adverse effects to the operation from the upper side substrate 12 to the lower side substrate 13, in a region in the vicinity of a specific circuit susceptible to adverse effects on the upper side substrate 12 due to the electromagnetic wave generated on the lower side substrate 13, or the like.

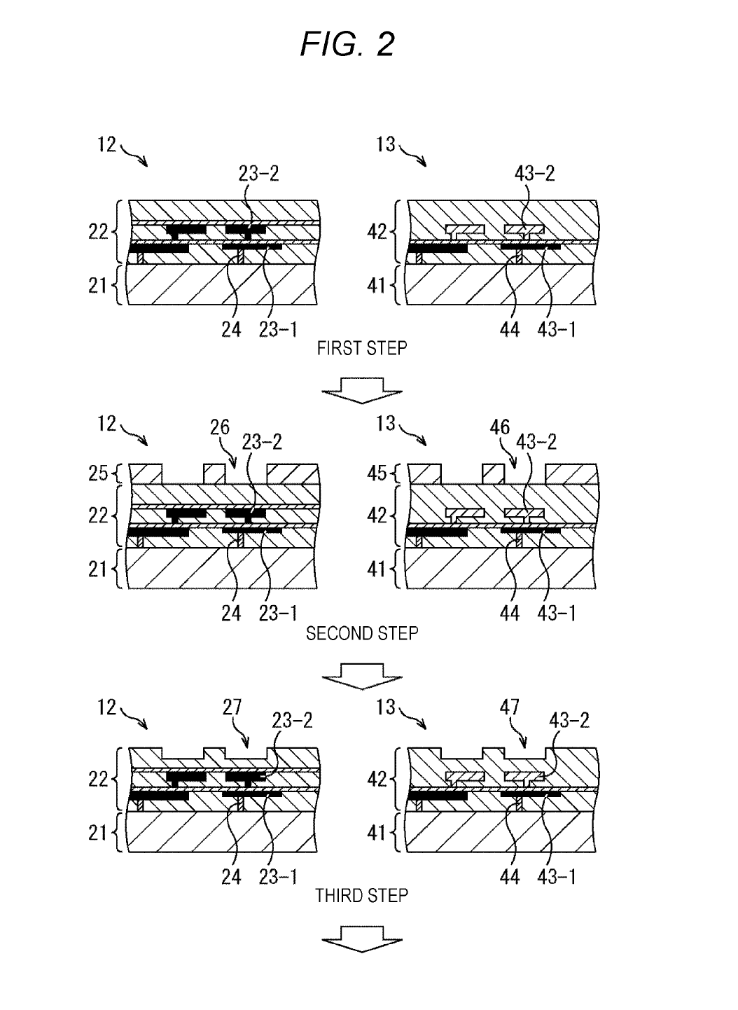

Next, a method for manufacturing the stacked device 11 will be described with reference to FIGS. 2 to 4. As described above, after the upper side substrate 12 and the lower side substrate 13 are formed separately from each other, the stacked device 11 is manufactured by stacking the upper side substrate 12 with the lower side substrate 13.

First, as illustrated in an upper-level portion of FIG. 2, a wiring layer 22 is formed so as to be stacked on a silicon substrate 21 on the upper side substrate 12 in a first step, and a wiring layer 42 is formed so as to be stacked on a silicon substrate 41 on the lower side substrate 13.

The wiring layer 22 of the upper side substrate 12 is formed with a multi-layer wiring structure in which a plurality of layers of wiring is formed within an interlayer insulating film. An exemplary configuration illustrated in FIGS. 2 to 4 is formed with a two-layer wiring structure in which wiring 23-1 on a lower layer side and wiring 23-2 on an upper layer side are stacked with each other. Moreover, the wiring layer 22 of the upper side substrate 12 is configured such that the wiring 23-1 is connected to the silicon substrate 21 via a connection electrode 24. Similarly, the wiring layer 42 of the lower side substrate 13 is configured with a two-layer wiring structure including wiring 43-1 on a lower layer side and wiring 43-2 on an upper layer side, and configured such that the wiring 43-1 is connected to the silicon substrate 41 via a connection electrode 44.

Meanwhile, for example, as an interlayer insulating film constituting each of the wiring layer 22 and the wiring layer 42, compositions such as silicon dioxide (SiO2), silicon nitride (SiN), carbon-containing silicon oxide (SiOCH), and carbon-containing silicon nitride (SiCN) are employed. Moreover, copper (Cu) wiring is employed as the wiring 23-1 and 23-2 of the wiring layer 22, and as the wiring 43-1 of wiring layer 42. Aluminum (Al) wiring is employed as the wiring 43-2 of the wiring layer 42. For these wiring forming methods, it is possible to use a known method disclosed by, for example, “Full Copper Wiring in a Sub-0.25 um CMOS ULSI Technology”, Proc. Of 1997 International Electron Device Meeting, pp. 773-776 (1997). Note that it is also allowable to apply a configuration in which the combination of Cu wiring and Al wiring employed for the upper side substrate 12 and the lower side substrate 13 is reversed, or in which both the upper side substrate 12 and the lower side substrate 13 employ any one of Cu wiring and Al wiring.

Next, in a second step, the upper side substrate 12 is processed such that, after resist 25 is applied to the wiring layer 22, an opening 26 is formed on the resist 25 using a general lithography technology, as illustrated in a middle-level portion of FIG. 2. Similarly, the lower side substrate 13 is processed such that, after resist 45 is applied to the wiring layer 42, an opening 46 is formed on the resist 45. Each of the resist 25 and the resist 45 is formed with a film thickness range of 0.05 μm to 5 μm, with allowable exemplary exposure light sources such as argon fluoride (ArF) excimer laser, krypton difluoride (KrF) excimer laser, and i-line (mercury spectral lines).

Subsequently, in a third step, etching is performed with a general dry etching technology, and thereafter, cleaning processing is performed. With this processing, as illustrated in a lower-level portion of FIG. 2, a trench 27 for forming the bonding pad 16 is formed on the upper side substrate 12, and a trench 47 for forming the bonding pad 17 is formed on the lower side substrate 13.

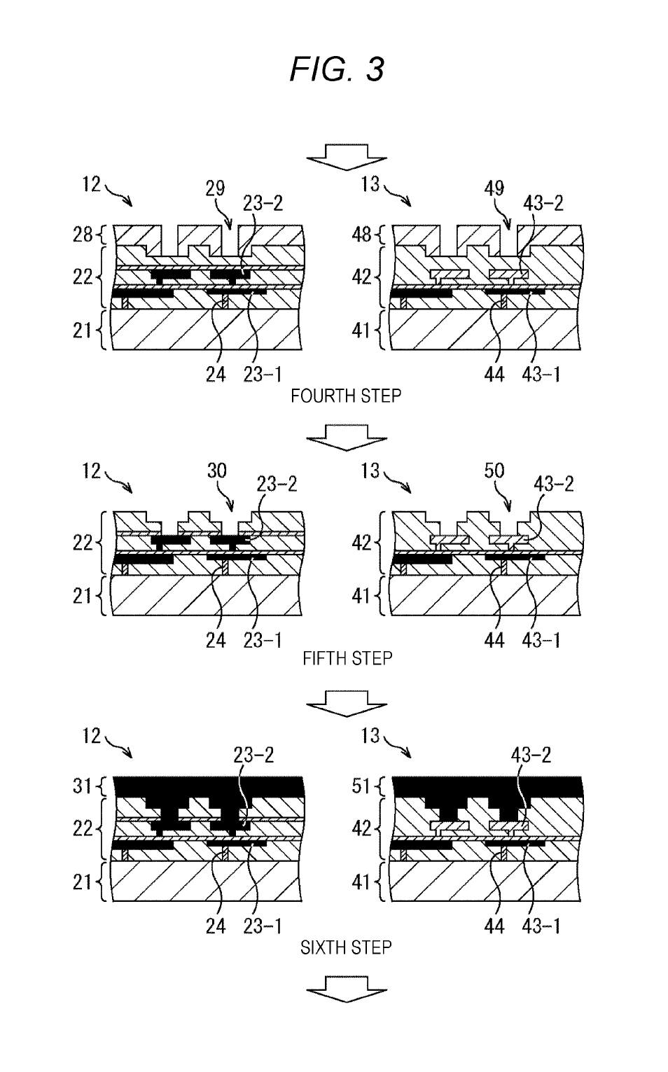

Next, in a fourth step, the upper side substrate 12 is processed such that, after resist 28 is applied to the wiring layer 22, an opening 29 is formed on the resist 28 so as to be smaller in size than the trench 27 using a general lithography technology, as illustrated in an upper-level portion of FIG. 3. Similarly, the lower side substrate 13 is processed such that, after resist 48 is applied to the wiring layer 42, an opening 49 is formed on the resist 48 so as to be smaller in size than the trench 47.

Subsequently, in a fifth step, etching is performed with a general dry etching technology, and thereafter, cleaning processing is performed. With this processing, as illustrated in a middle-level portion of FIG. 3, a trench 30 is formed on the upper side substrate 12. The trench 30 is used for forming a via for connecting the bonding pad 16 to the wiring 23-2. Similarly, a trench 50 is formed on the lower side substrate 13. The trench 50 is used for forming a via for connecting the bonding pad 17 to the wiring 43-2.

Thereafter, in a sixth step, using high-frequency sputtering processing, titanium (Ti), tantalum (Ta), ruthenium (Ru) or nitride thereof are formed into a film having a thickness of 5 nm to 50 nm in Ar/N2 atmosphere as a Cu barrier, and then, a Cu film is deposited by electrolytic plating or a sputtering method. With this processing, as illustrated in a lower-level portion of FIG. 3, a Cu film 31 is formed on the upper side substrate 12 so as to fill the trench 30, and a Cu film 51 is formed on the lower side substrate 13 so as to fill the trench 50.

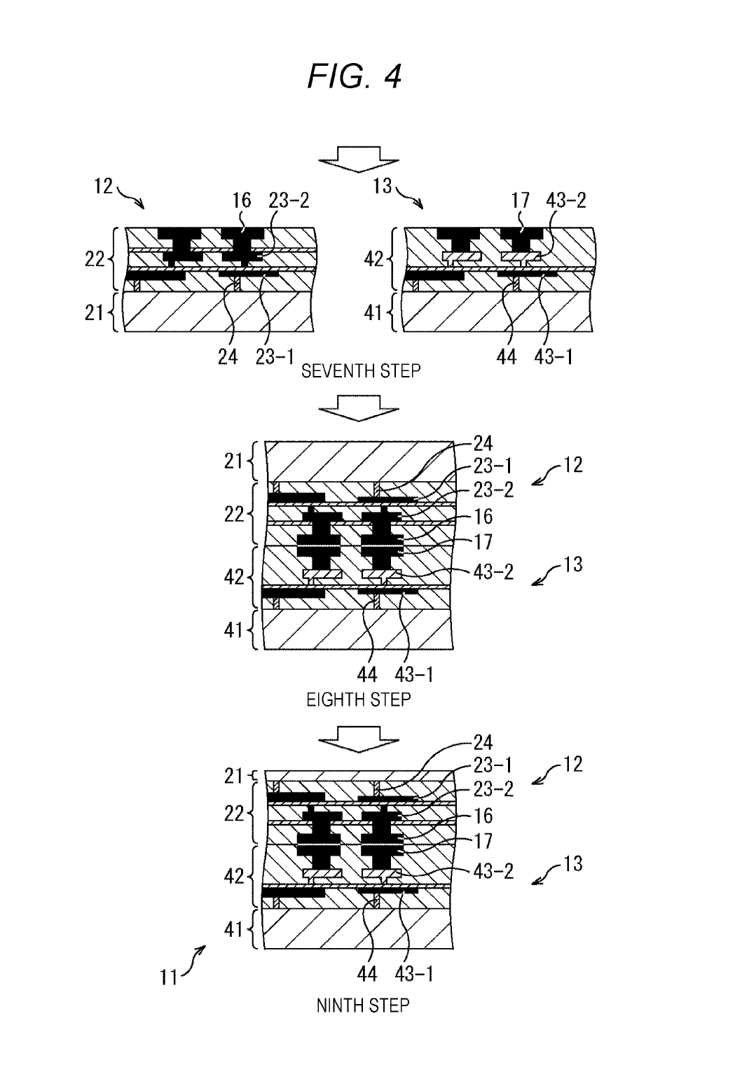

Next, in a seventh step, using a hot plate and sinter annealing device, heat treatment is performed for about one minute to 60 minutes at a temperature of 100° C. to 400° C. Thereafter, an unnecessary portion as the bonding pad 16 and the bonding pad 17 is removed, among the deposited Cu barrier, the Cu film 31, and the Cu film 51, using a chemical mechanical polishing (CMP) method. This processing leaves portions filled into the trench 30 and the trench 50, so as to form the bonding pad 16 and the bonding pad 17 as illustrated in an upper-level portion of FIG. 4.

Moreover, in an eighth step, as illustrated in a middle-level portion of FIG. 4, processing is performed to bond the upper side substrate 12 with the lower side substrate 13 by metal-bonding the bonding pad 16 and the bonding pad 17 with each other.

Subsequently, in a ninth step, as illustrated in a lower-level portion of FIG. 4, the silicon substrate 21 of the upper side substrate 12 is grounded and polished, from an upper-side portion of FIG. 4, so as to perform thinning processing such that the thickness of the upper side substrate 12 becomes about 5 μm to 10 μm. Steps thereafter differ depending on the usage of the stacked device 11. For example, in a case of using the device as a stacked solid-state imaging element, the stacked device 11 is produced using a manufacturing method disclosed in Patent Document 3. Moreover, processing in the steps thereafter, as illustrated in FIG. 1, includes processing of connecting the bonding pad 17 to a circuit that performs electrical fixing.

Using a manufacturing method including the above individual steps, it is possible to manufacture the stacked device 11 including an electromagnetic wave shield structure that interrupts the electromagnetic wave between the upper side substrate 12 and the lower side substrate 13. Moreover, the stacked device 11 is configured such that the upper side substrate 12 and the lower side substrate 13 are bonded with each other by metal-bonding of the bonding pad 16 and the bonding pad 17. Accordingly, for example, it is possible to achieve an enhanced bonding force compared with a case of bonding metal with an insulating film and to avoid an occurrence of broken wafer during production.

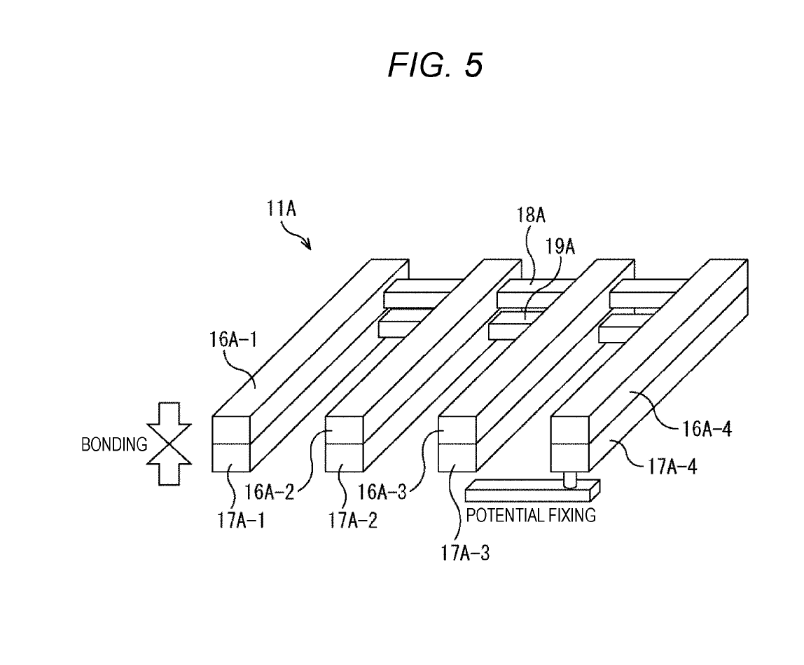

FIG. 5 is a diagram illustrating an exemplary configuration of the stacked device 11 according to a second embodiment.

FIG. 5 illustrates a bonding pad 16A and a bonding pad 17A formed on a bonding surface of a stacked device 11A, with illustrations of other configurations being omitted because they are similar to the case of the stacked device 11. Moreover, a method for manufacturing the stacked device 11A is similar to the case of the stacked device 11 described with reference to FIGS. 2 to 4.

As illustrated in FIG. 5, the stacked device 11A is configured such that each of the bonding pads 16A and the bonding pads 17A is linearly formed independently from each other, with the bonding pad 16A and the bonding pad 17A being metal-bonded with each other on the entire surfaces. For example, each of the bonding pad 16A and the bonding pad 17A is formed with a length of a long side being 100 μm, and is arranged in a pattern at intervals of 0.005 μm to 1000 μm.

Moreover, FIG. 5 illustrates four bonding pads 16A-1 to 16A-4 and four bonding pads 17A-1 to 17A-4, among the plurality of bonding pads 16A and the plurality of bonding pads 17A. In addition, adjoining pads among the bonding pads 16A-1 to 16A-4 are coupled with each other by coupling wiring 18A formed in a same layer, and adjoining pads among the bonding pads 17A-1 to 17A-4 are coupled with each other by coupling wiring 19A formed in a same layer. Furthermore, at least one of the bonding pads 16A-1 to 16A-4 and the bonding pad 17A-1 to 17A-4 is connected to a circuit that is electrically fixed. In a configuration example of FIG. 5, for example, the bonding pad 17A-4 is potential-fixed.

In this manner, the stacked device 11A is capable of achieving an electromagnetic wave shield configuration by metal-bonding the linearly formed bonding pad 16A and the bonding pad 17A with each other and then, by performing potential fixing. With this configuration, the stacked device 11A is capable of suppressing a situation where the noise due to the electromagnetic wave generated at the time of operation produces adverse effects.

Note that the stacked device 11A can be configured to include the electromagnetic wave shield configuration formed with the bonding pad 16A and the bonding pad 17A on the entire surface of the stacked device 11A, for example. Alternatively, for example, it is allowable to arrange the electromagnetic wave shield configuration formed with the bonding pad 16A and the bonding pad 17A, in a region in the vicinity of a specific circuit that generates an electromagnetic wave that produces adverse effects and in a region in the vicinity of a specific circuit susceptible to adverse effects.

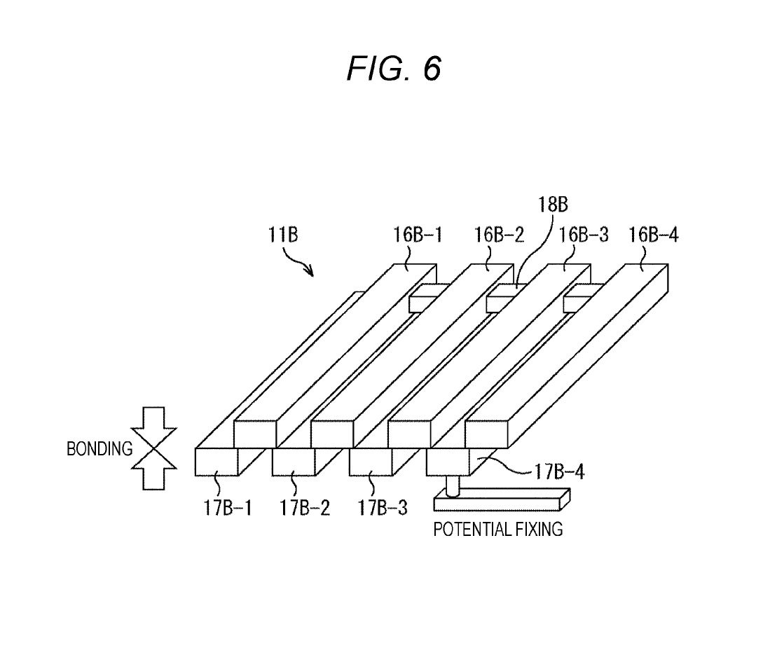

FIG. 6 is a diagram illustrating an exemplary configuration of the stacked device 11 according to a third embodiment.

FIG. 6 illustrates a bonding pad 16B and a bonding pad 17B formed on a bonding surface of a stacked device 11B, with illustrations of other configurations being omitted because they are similar to the case of the stacked device 11. Moreover, a method for manufacturing the stacked device 11B is similar to the case of the stacked device 11 described with reference to FIGS. 2 to 4.

As illustrated in FIG. 6, the stacked device 11B is configured such that the bonding pad 16B and the bonding pad 17B are linearly formed independently from each other, similarly to the case of the stacked device 11A in FIG. 5.

Subsequently, the stacked device 11B forms an electromagnetic wave shield configuration by arranging the bonding pad 16B and the bonding pad 17B at positions shifted from each other, with a portion of each of the pads being metal-bonded with each other and potential fixed. For example, a bonding pad 16B-1 is arranged between a bonding pad 17B-1 and a bonding pad 17B-2, partially being metal-bonded at a portion overlapping with the bonding pad 17B-1 and the bonding pad 17B-2. Similarly, a bonding pad 17B-2 is arranged between a bonding pad 16B-2 and a bonding pad 16B-3, partially being metal-bonded at a portion overlapping with the bonding pad 16B-2 and the bonding pad 16B-3.

In this manner, the stacked device 11B is configured such that the bonding pad 16B and the bonding pad 17B are arranged at mutually shifted positions, that is, the plurality of bonding pads 17B is arranged at a position that blocks an interval between the plurality of bonding pads 16B, with a mutually overlapping portion being partially metal-bonded with each other. With this arrangement, the stacked device 11B is configured to have an appearance that an entire bonding surface is covered with the bonding pads 16B and the bonding pads 17B, and to have an appearance that metal is arranged on an entire surface of the bonding surface in a top view or a bottom view.

Accordingly, the stacked device 11B with this configuration is capable of further reliably suppressing a situation where the noise due to the electromagnetic wave generated at the time of operation produces adverse effects by using the electromagnetic wave shield configuration to appear that metal is arranged on an entire surface of the bonding surface.

Note that the stacked device 11B can be configured to include the electromagnetic wave shield configuration formed with the bonding pad 16B and the bonding pad 17B on the entire surface of the stacked device 11B, for example. Alternatively, for example, it is allowable to arrange the electromagnetic wave shield configuration formed with the bonding pad 16B and the bonding pad 17B, in a region in the vicinity of a specific circuit that generates an electromagnetic wave that produces adverse effects and in a region in the vicinity of a specific circuit susceptible to adverse effects.

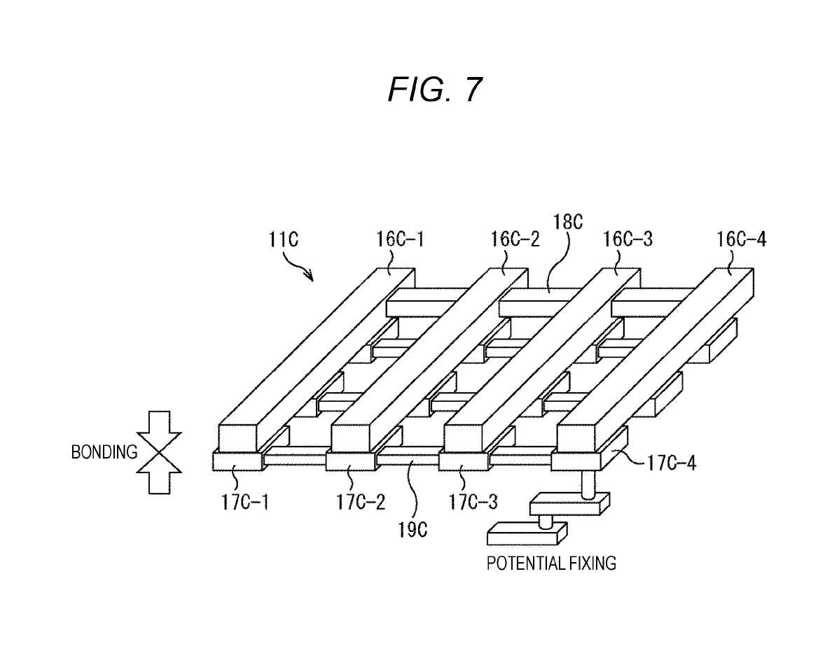

FIG. 7 is a diagram illustrating an exemplary configuration of the stacked device 11 according to a fourth embodiment.

FIG. 7 illustrates a bonding pad 16C and a bonding pad 17C formed on a bonding surface of a stacked device 11C, with illustrations of other configurations being omitted because they are similar to the case of the stacked device 11. Moreover, a method for manufacturing the stacked device 11C is similar to the case of the stacked device 11 described with reference to FIGS. 2 to 4.

As illustrated in FIG. 7, the stacked device 11C is configured such that the bonding pad 16C is linearly formed similarly to the bonding pad 16A in FIG. 5, and that the bonding pad 17C is formed in a rectangular shape similarly to the bonding pad 17 in FIG. 1. In this manner, the stacked device 11C is capable of achieving an electromagnetic wave shield configuration by metal-bonding the linearly formed bonding pad 16C and the rectangular-shaped bonding pad 17C with each other and then, by performing potential fixing. With this configuration, the stacked device 11C is capable of further reliably suppressing a situation where the noise due to the electromagnetic wave generated at the time of operation produces adverse effects.

Note that the stacked device 11C can be configured to include the electromagnetic wave shield configuration formed with the bonding pad 16C and the bonding pad 17C on the entire surface of the stacked device 11C, for example. Alternatively, for example, it is allowable to arrange the electromagnetic wave shield configuration formed with the bonding pad 16C and the bonding pad 17C, in a region in the vicinity of a specific circuit that generates an electromagnetic wave that produces adverse effects and in a region in the vicinity of a specific circuit susceptible to adverse effects.

Moreover, it is allowable to configure as a modification example of the stacked device 11C such that the bonding pad 16C is formed into a rectangular shape similarly to the bonding pad 17 in FIG. 1, and that the bonding pad 17C is linearly formed similarly to the bonding pad 16A in FIG. 5.

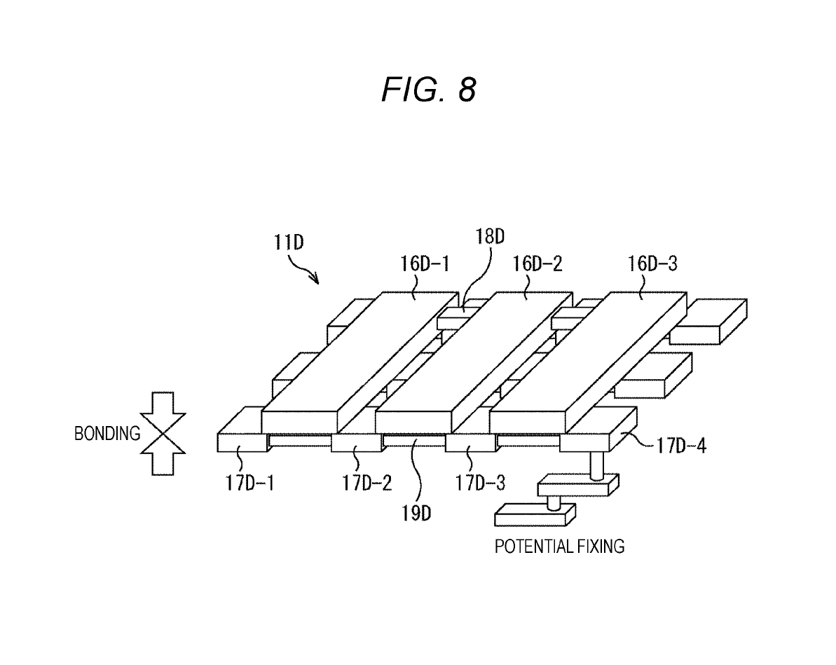

FIG. 8 is a diagram illustrating an exemplary configuration of the stacked device 11 according to a fifth embodiment.

FIG. 8 illustrates a bonding pad 16D and a bonding pad 17D formed on a bonding surface of a stacked device 11D, with illustrations of other configurations being omitted because they are similar to the case of the stacked device 11. Moreover, a method for manufacturing the stacked device 11D is similar to the case of the stacked device 11 described with reference to FIGS. 2 to 4.

As illustrated in FIG. 8, the stacked device 11D is configured such that the bonding pad 16D is linearly formed similarly to the bonding pad 16A in FIG. 5, and that the bonding pad 17D is formed in a rectangular shape similarly to the bonding pad 17 in FIG. 1. Moreover, similar to the stacked device 11B in FIG. 6, the stacked device 11D forms an electromagnetic wave shield configuration by arranging the bonding pad 16D and the bonding pad 17D at positions shifted from each other, with a portion of each of the pads being metal-bonded with each other and potential fixed.

In this manner, the stacked device 11D is configured such that the bonding pad 16D and the bonding pad 17D are arranged at positions shifted from each other, making it possible to arrange metal in a wider bonding surface area compared with the configuration in FIG. 1, for example. Accordingly, the stacked device 11D with this configuration is capable of further reliably suppressing a situation where the noise due to the electromagnetic wave generated at the time of operation produces adverse effects.

Note that the stacked device 11D can be configured to include the electromagnetic wave shield configuration formed with the bonding pad 16D and the bonding pad 17D on the entire surfaces of the stacked device 11D, for example. Alternatively, for example, it is allowable to arrange the electromagnetic wave shield configuration formed with the bonding pad 16D and the bonding pad 17D, in a region in the vicinity of a specific circuit that generates an electromagnetic wave that produces adverse effects and in a region in the vicinity of a specific circuit susceptible to adverse effects.

Moreover, it is allowable to configure as a modification example of the stacked device 11D such that the bonding pad 16D is formed into a rectangular shape similarly to the bonding pad 17 in FIG. 1, and that the bonding pad 17D is linearly formed similarly to the bonding pad 16A in FIG. 5.

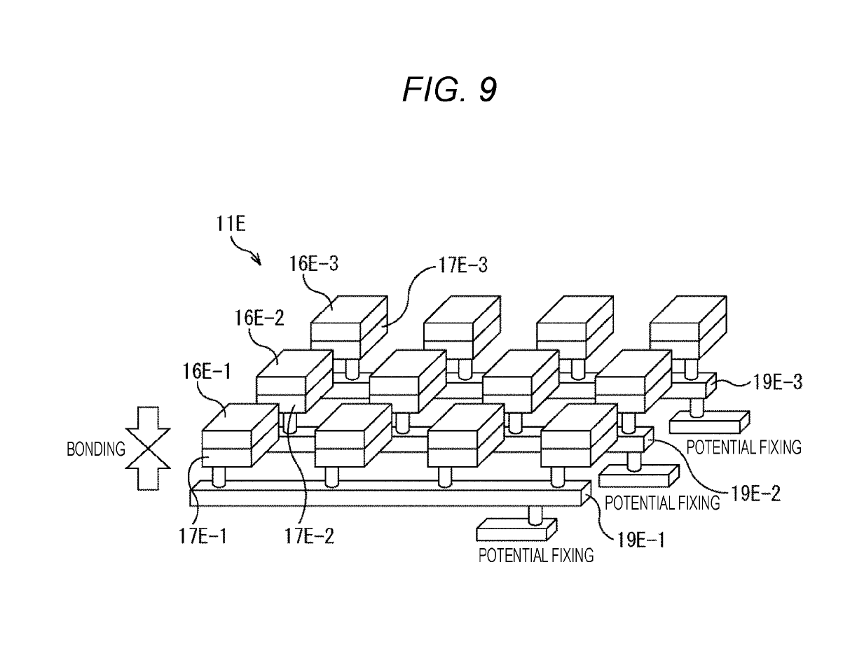

FIG. 9 is a diagram illustrating an exemplary configuration of the stacked device 11 according to a sixth embodiment.

FIG. 9 illustrates a bonding pad 16E and a bonding pad 17E formed on a bonding surface of a stacked device 11E, with illustrations of other configurations being omitted because they are similar to the case of the stacked device 11. Moreover, a method for manufacturing the stacked device 11E is similar to the case of the stacked device 11 described with reference to FIGS. 2 to 4.

In each of the above-described embodiments, the bonding pad 16 and the bonding pad 17 are configured to be respectively connected by the coupling wiring 18 and the coupling wiring 19, each of which being formed in a same layer. In contrast, the stacked device 11E has a configuration in which coupling wiring 19E is formed in a layer different from the bonding pad 16E and from the bonding pad 17E, and the bonding pad 16E and the bonding pad 17E are electrically connected via the coupling wiring 19E.

For example, as illustrated in FIG. 9, a row in which a bonding pad 16E-1 and a bonding pad 17E-1 are arranged achieves connection via coupling wiring 19E-1, and then potential fixing is performed. Moreover, a row in which a bonding pad 16E-2 and a bonding pad 17E-2 are arranged achieves connection via coupling wiring 19E-2 and then, potential fixing is performed. A row in which a bonding pad 16E-3 and a bonding pad 17E-3 are arranged achieves connection via coupling wiring 19E-3, and then, potential fixing is performed.

In this manner, it is possible to achieve the electromagnetic wave shield configuration by providing the coupling wiring 19E that connects the bonding pad 16E with the bonding pad 17E, in a layer different from the bonding pad 16E and from the bonding pad 17E.

Note that the stacked device 11E can be configured to include the electromagnetic wave shield configuration formed with the bonding pad 16E and the bonding pad 17E on the entire surfaces of the stacked device 11E, for example. Alternatively, for example, it is allowable to arrange the electromagnetic wave shield configuration formed with the bonding pad 16E and the bonding pad 17E, in a region in the vicinity of a specific circuit that generates an electromagnetic wave that produces adverse effects and in a region in the vicinity of a specific circuit susceptible to adverse effects.

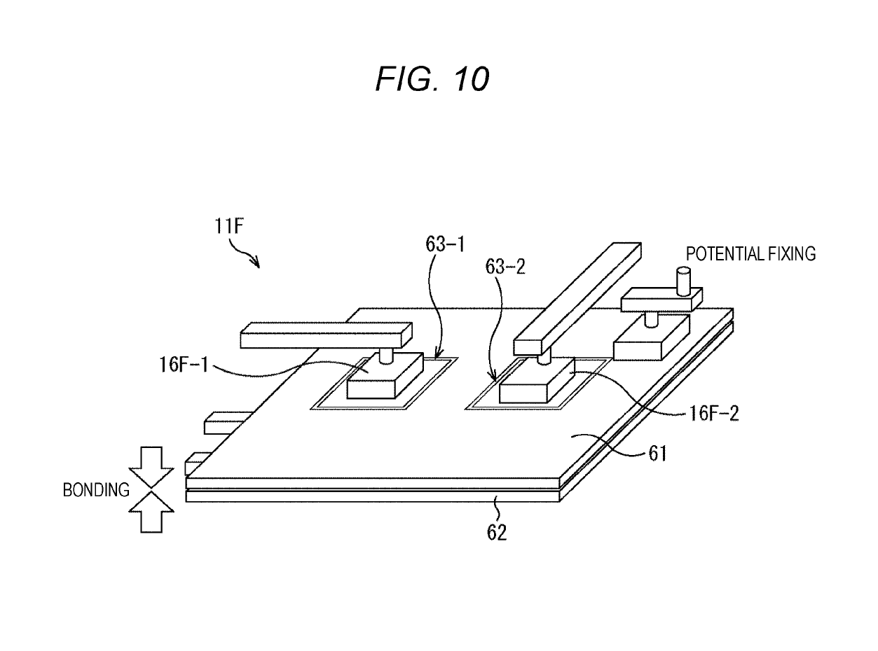

FIG. 10 is a diagram illustrating an exemplary configuration of the stacked device 11 according to a seventh embodiment.

As illustrated in FIG. 10, a stacked device 11F is configured such that a metal layer 61 is formed on the entire surface of the bonding surface 14 (refer to FIG. 1) of an upper side substrate 12F, while a metal layer 62 is formed on the entire surface of the bonding surface 15 (refer to FIG. 1) of a lower side substrate 13F. Moreover, the stacked device 11F is configured such that a connecting portion that electrically connects the upper side substrate 12F with the lower side substrate 13F is electrically independent from the metal layer 61 by slits, for example, formed to have a width ranging from 0.01 μn to 100 μn. In an exemplary configuration illustrated in FIG. 10, a slit 63-1 is formed so as to enclose a bonding pad 16F-1 as a connecting portion, and a slit 63-2 is formed so as to enclose a bonding pad 16F-2 as a connecting portion. Moreover, the stacked device 11F is configured such that a portion of the metal layer 61 and the metal layer 62, specifically, the metal layer 61 in an exemplary configuration in FIG. 10, is connected to a circuit that is electrically fixed.

The stacked device 11F with this configuration is capable of further reliably interrupting an electromagnetic wave between the upper side substrate 12F and the lower side substrate 13F by its electromagnetic wave shield configuration achieved by bonding the metal layer 61 and the metal layer 62 and then by performing potential fixing. Accordingly, the stacked device 11F is capable of further reliably suppressing a situation where the noise due to the electromagnetic wave generated at the time of operation produces adverse effects.

Note that the stacked device 11F can be configured to include the electromagnetic wave shield configuration formed with the metal layer 61 and the metal layer 62 on the entire surface of the stacked device 11F, for example. Alternatively, for example, it is allowable to arrange the electromagnetic wave shield configuration formed with the metal layer 61 and the metal layer 62, in a region in the vicinity of a specific circuit that generates an electromagnetic wave that produces adverse effects and in a region in the vicinity of a specific circuit susceptible to adverse effects.

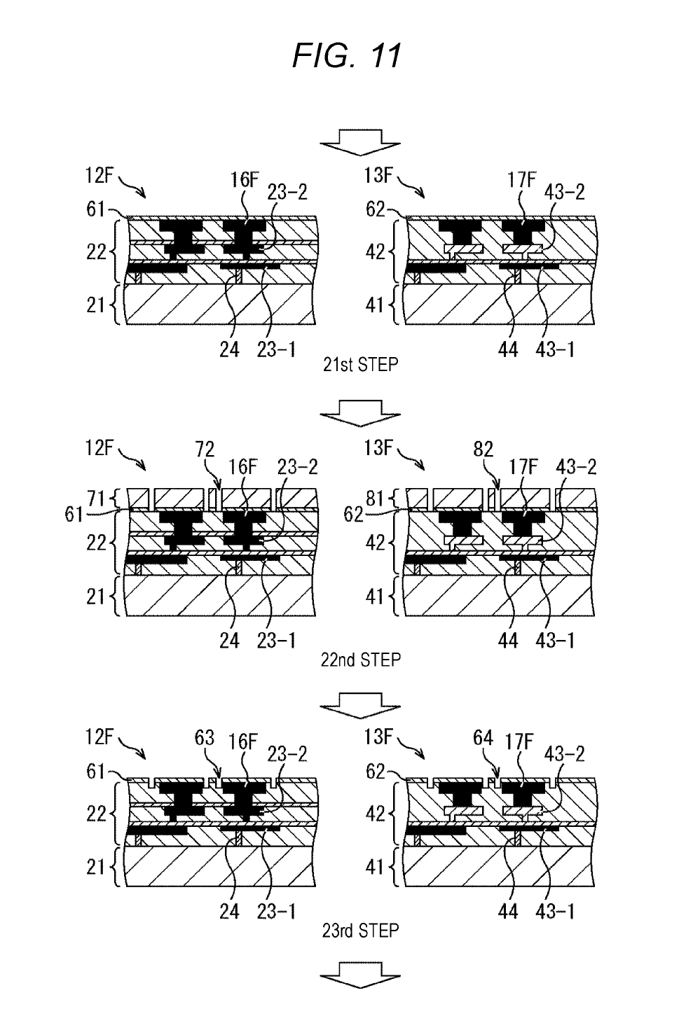

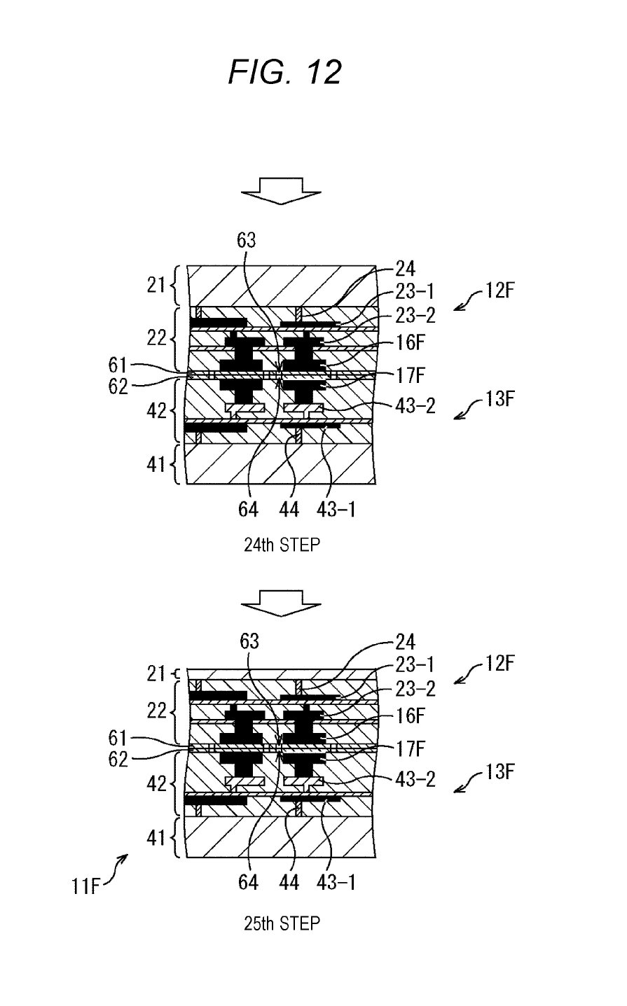

Next, a method for manufacturing the stacked device 11F will be described with reference to FIGS. 11 and 12. Note that description will be omitted for the first to seventh steps (refer to FIGS. 2 to 4) that illustrate a method for manufacturing the stacked device 11 in FIG. 1 because the steps to be performed are the same, and thus, description will be given from a 21st step, which comes next to the seventh step.

In the 21st step as illustrated in an upper-level portion of FIG. 11, the upper side substrate 12F forms the metal layer 61 using RF sputtering processing and vapor deposition processing onto the wiring layer 22 in which the bonding pad 16F has been formed in the seventh step illustrated in FIG. 4. Similarly, the lower side substrate 13F forms the metal layer 62 onto the wiring layer 42 in which the bonding pad 17F has been formed. Each of the metal layer 61 and the metal layer 62 is formed using conductive metal materials such as Cu, CuO, Ta, TaN, Ti, TiN, W, WN, Ru, RuN, and Co, so as to have a thickness ranging 0.1 nm to 1000 nm.

Next, in a 22nd step, the upper side substrate 12F is processed such that, after resist 71 is applied to the metal layer 61, an opening 72 is formed on the resist 71 using a general lithography technology so as to enclose the bonding pad 16F, as illustrated in a middle-level portion of FIG. 11. Similarly, the lower side substrate 13F is processed such that, after resist 81 is applied to the metal layer 62, an opening 82 is formed on the resist 81 so as to enclose the bonding pad 17F.

Subsequently, in a 23rd step, etching is performed with a general dry etching technology, and thereafter, cleaning processing is performed. With this processing, as illustrated in a lower-level portion of FIG. 11, a slit 63 is formed on the metal layer 61 of the upper side substrate 12F, while a slit 64 is formed on the metal layer 62 of the lower side substrate 13F.

Moreover, in a 24th step, as illustrated in an upper-level portion of FIG. 12, processing is performed to bond the upper side substrate 12F with the lower side substrate 13F by metal-bonding the metal layer 61 and the metal layer 62 with each other. At this time, the bonding pad 16F and the bonding pad 17F are bonded with each other electrically independently from the metal layer 61 and the metal layer 62 because of a slit 63 and a slit 64.

Next, in a 25th step, as illustrated in a lower-level portion of FIG. 12, the silicon substrate 21 of the upper side substrate 12F is grounded and polished starting from an upper-side of FIG. 12, so as to perform thinning processing such that the thickness of the upper side substrate 12F becomes about 5 μm to 10 μm. Steps thereafter would differ depending on the usage of the stacked device 11F. For example, in a case where the usage is for a stacked solid-state imaging element, the stacked device 11F is produced using a manufacturing method disclosed in Patent Document 3.

Using a manufacturing method including the above individual steps, it is possible to manufacture the stacked device 11F including an electromagnetic wave shield structure that interrupts the electromagnetic wave between the upper side substrate 12F and the lower side substrate 13F. Moreover, the stacked device 11F is configured such that the upper side substrate 12F and the lower side substrate 13F are mutually bonded by metal-bonding of the metal layer 61 and the metal layer 62. Accordingly, for example, it is possible to achieve an enhanced bonding force compared with a case of bonding metal with an insulating film and to avoid an occurrence of a broken wafer during production.

Note that while the present embodiment describes the stacked device 11 with a two-layer structure, the present technology can be applied to the stacked device 11 in which three or more layered substrates are stacked.

Moreover, the electromagnetic wave shield structure according to the present embodiment can be configured by appropriately selecting and combining each of the above-described configurations including the shapes of metal layers formed on the bonding surfaces (bonding pads 16 and 17, and metal layers 61 and 62), methods for (entirely or partially) bonding metal layers with each other), and arrangement positions of electromagnetic wave shield structures.

Note that the stacked device 11 according to each of the above-described embodiments can be applied, for example, to a solid-state imaging element that captures an image. In addition the solid-state imaging element configured as the stacked device 11 can be applied, for example, to various electronic apparatuses including imaging systems such as a digital still camera and a digital video camera, a mobile phone having an imaging function, or other electronic instruments having an imaging function.

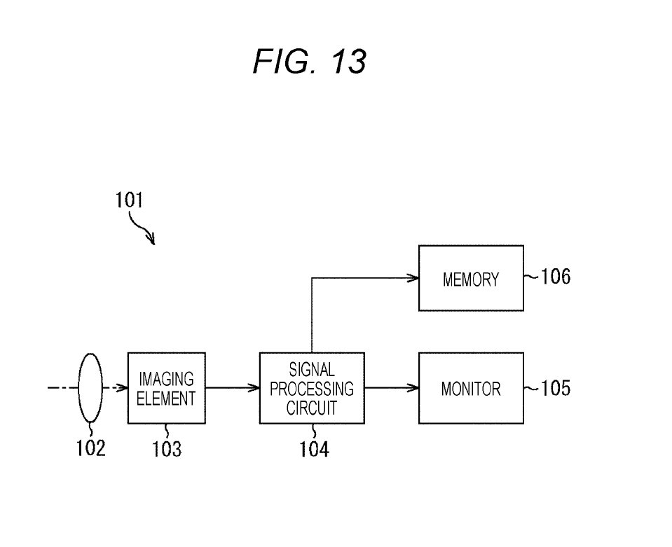

FIG. 13 is a block diagram illustrating an exemplary configuration of an imaging apparatus mounted on an electronic instrument.

As illustrated in FIG. 13, an imaging apparatus 101 includes an optical system 102, an imaging element 103, a signal processing circuit 104, a monitor 105, and a memory 106, and is capable of capturing a still image and a moving image.

The optical system 102 includes one or more lenses, introduces image light (incident light) from a subject to the imaging element 103, and forms an image on a light receiving surface (sensor unit) of the imaging element 103.

The imaging element 103 is configured as the stacked device 11 according to each of the above-described embodiments. The imaging element 103 stores electrons for a fixed period of time in accordance with an image formed on the light receiving surface via the optical system 102. Subsequently, a signal generated in accordance with the electrons stored in the imaging element 103 is supplied to the signal processing circuit 104.

The signal processing circuit 104 performs various signal processing on a pixel signal output from the imaging element 103. The image (image data) obtained by the signal processing performed by the signal processing circuit 104 is supplied to and displayed on the monitor 105, or supplied to and stored (recorded) in the memory 106.

With application of the stacked device 11 according to each of the above-described embodiments in the imaging apparatus 101 with this configuration, it is possible to capture an image with higher image quality and a lower noise level.

Note that the present technology may also be configured as below.

(1)

A stacked device including:
a first metal layer formed on one substrate of a plurality of substrates formed with at least two stacked layers; and
a second metal layer formed on the other substrate stacked with the one substrate,
in which an electromagnetic wave shield structure that interrupts an electromagnetic wave between the one substrate and the other substrate is provided by bonding the first metal layer and the second metal layer with each other and performing potential fixing.
   (2)

The stacked device according to the above-described (1),
in which the first metal layer is formed so as to be exposed on a bonding surface that bonds the one substrate with the other substrate, and
the second metal layer is formed so as to be exposed on a bonding surface that bonds the other substrate with the one substrate.
   (3)

The stacked device according to the above-described (1) or (2),
in which each of the first metal layer and the second metal layer includes a plurality of pads arranged independently at a predetermined interval between each other.
   (4)

The stacked device according to the above-described (3),
in which at least a portion of the plurality of pads constituting each of the first metal layer and the second metal layer is electrically connected with each other via coupling wiring formed respectively in a same layer as each of the first metal layer and the second metal layer.
   (5)

The stacked device according to any of the above-described (3) and (4),
in which the plurality of pads constituting the first metal layer and the plurality of pads constituting the second metal layer are mutually bonded on entire surfaces or a portion of the surfaces.
   (6)

The stacked device according to the above-described (3),
in which at least a portion of the plurality of pads constituting each of the first metal layer and the second metal layer is electrically connected with each other via wiring formed in a layer different from the first metal layer and the second metal layer.
   (7)

The stacked device according to the above-described (1) or (2),
in which the first metal layer and the second metal layer are formed on an entire surface other than a bonding portion that performs electrical connection between the one substrate and the other substrate, and
a slit is formed between the first metal layer and the bonding portion, and between the second metal layer and the bonding portion.
   (8)

The stacked device according to any of the above-described (1) or (7),
in which the electromagnetic wave shield structure is arranged on an entire surface of each of the bonding surface of the one substrate and the other substrate.
   (9)

The stacked device according to any of the above-described (1) or (7),
in which the electromagnetic wave shield structure is arranged, on a bonding surface of each of the one substrate and the other substrate, in at least any one region of a region that generates an electromagnetic wave that produces adverse effects to an operation from the one substrate to the other substrate,
and a region that is adversely affected on the one substrate by the electromagnetic wave that is generated on the other substrate.
   (10)

A stacked device manufacturing method including steps of:
forming a first metal layer on one substrate of a plurality of substrates formed with at least two stacked layers;
forming a second metal layer on the other substrate stacked with the one substrate; and
providing an electromagnetic wave shield structure that interrupts an electromagnetic wave between the one substrate and the other substrate by bonding the first metal layer and the second metal layer with each other and performing potential fixing.
   (11)

An electronic instrument equipped with a stacked device including:
a first metal layer formed on one substrate of a plurality of substrates formed with at least two stacked layers; and
a second metal layer formed on the other substrate stacked with the one substrate,
in which an electromagnetic wave shield structure that interrupts an electromagnetic wave between the one substrate and the other substrate is provided by bonding the first metal layer and the second metal layer with each other and performing potential fixing.

Note that embodiments of the present technology are not limited to the above-described embodiments but can be modified in a variety of ways within a scope of the present disclosure.

### REFERENCE SIGNS LIST

11 stacked device
12 upper side substrate
13 lower side substrate
14 and 15 bonding surface
16 and 17 bonding pad
18 and 19 coupling wiring
21 silicon substrate
22 wiring layer
23 wiring
24 connection electrode
25 resist
26 opening
27 trench
28 resist
29 opening
30 trench
31 Cu film
41 silicon substrate
42 wiring layer
43 wiring
44 connection electrode
45 resist
46 opening
47 trench
48 resist
49 opening
50 trench
51 Cu film
61 and 62 metal layer
63 and 64 slit
71 resist
72 opening
81 resist
82 opening

What is claimed is:

1. A stacked device comprising:
a first metal layer formed on one substrate of a plurality of substrates formed with at least two stacked layers; and
a second metal layer formed on the other substrate stacked with the one substrate,
wherein an electromagnetic wave shield structure that interrupts an electromagnetic wave between the one substrate and the other substrate is provided by bonding the first metal layer and the second metal layer with each other and performing potential fixing.

2. The stacked device according to claim 1,
wherein the first metal layer is formed so as to be exposed on a bonding surface that bonds the one substrate with the other substrate, and
the second metal layer is formed so as to be exposed on a bonding surface that bonds the other substrate with the one substrate.

3. The stacked device according to claim 2,
wherein each of the first metal layer and the second metal layer includes a plurality of pads arranged independently at a predetermined interval between each other.

4. The stacked device according to claim 3,
wherein at least a portion of the plurality of pads constituting each of the first metal layer and the second metal layer is electrically connected with each other via coupling wiring formed in a same layer as each of the first metal layer and the second metal layer.

5. The stacked device according to claim 3,
wherein the plurality of pads constituting the first metal layer and the plurality of pads constituting the second metal layer are mutually bonded on entire surfaces or a portion of the surfaces.

6. The stacked device according to claim 3,
wherein at least a portion of the plurality of pads constituting each of the first metal layer and the second metal layer is electrically connected with each other via wiring formed in a layer different from the first metal layer and the second metal layer.

7. The stacked device according to claim 2,
wherein the first metal layer and the second metal layer are formed on an entire surface other than a bonding portion that performs electrical connection between the one substrate and the other substrate, and
a slit is formed between the first metal layer and the bonding portion, and between the second metal layer and the bonding portion.

8. The stacked device according to claim 1,
wherein the electromagnetic wave shield structure is arranged on an entire surface of each of the bonding surface of the one substrate and the other substrate.

9. The stacked device according to claim 1,
wherein the electromagnetic wave shield structure is arranged, on a bonding surface of each the one substrate and the other substrate, in at least any one region of a region that generates an electromagnetic wave that produces adverse effects to an operation from the one substrate to the other substrate,
and a region that is adversely affected on the one substrate by the electromagnetic wave that is generated on the other substrate.

10. A stacked device manufacturing method comprising steps of:
forming a first metal layer on one substrate of a plurality of substrates formed with at least two stacked layers;
forming a second metal layer on the other substrate stacked with the one substrate; and
providing an electromagnetic wave shield structure that interrupts an electromagnetic wave between the one substrate and the other substrate by bonding the first metal layer and the second metal layer with each other and performing potential fixing.

11. An electronic instrument equipped with a stacked device comprising:
a first metal layer formed on one substrate of a plurality of substrates formed with at least two stacked layers; and
a second metal layer formed on the other substrate stacked with the one substrate,
wherein an electromagnetic wave shield structure that interrupts an electromagnetic wave between the one substrate and the other substrate is provided by bonding the first metal layer and the second metal layer with each other and performing potential fixing.
